(19) United States
(12) Patent Application Publication
(10) Pub. No.: US 2026/0303011 A1
(43) Pub. Date: Oct. 1, 2026

(54) TANDEM SOLAR CELL MODULE ASSEMBLY

(71) Applicant: TSEC Corporation, New Taipei City (TW)

(72) Inventors: Che-Wei Hsu, Kaohsiung City (TW); Kang-Feng Fan, Taoyuan City (TW); Li-Wei Tu, Pingtung County (TW); Cheng-Wen Kuo, Kaohsiung City (TW); Ta-Ming Kuan, Hsinchu City (TW); Chun-Wei Lee, Taoyuan City (TW); Cheng-Yeh Yu, Hsinchu City (TW)

(73) Assignee: TSEC Corporation, New Taipei City (TW)

(21) Appl. No.: 19/186,698

(22) Filed: Apr. 23, 2025

(30) Foreign Application Priority Data
Mar. 31, 2025 (TW) 114112265

(51) Int. Cl. H02S 30/10; H10F 10/172

(52) U.S. Cl. CPC H02S 30/10; H10F 10/172

(57) ABSTRACT

A solar cell stack module includes a frame with a flange disposed along the inner perimeter of the frame; a lower solar cell module disposed in the frame and supported by the flange; an upper solar cell module disposed in the frame and stacked on the lower solar cell module; and a top cover stacked on the upper solar cell module.

### BACKGROUND OF THE INVENTION

### 1. Field of the Invention

This invention relates to the field of solar energy technology, and more particularly, to a tandem solar cell module assembly wherein at least two solar cell modules are fixed and installed in the same frame structure.

### 2. Description of the Prior Art

In recent years, solar energy technology has seen continuous development in conversion efficiency and power output. Scientists have dedicated substantial effort to achieving breakthroughs in various materials. While these efforts have yielded significant results, it also suggests that these materials will eventually encounter theoretical limitations, leading to stagnation. Consequently, there's growing interest in tandem cells, which combine the advantages of different materials to potentially overcome these limitations.

A notable tandem cell configuration in recent years involves a combination of perovskite and silicon-based cells. Perovskite cells primarily excel in short-wavelength conversion, whereas silicon-based cells are more efficient in long-wavelength conversion. Combining these can boost the efficiency of Tunnel Oxide Passivated Contact (TOPCon) cells from 24-26% to over 30%. However, current mature tandem cells are mostly 2T tandem cells, where perovskite cells are fabricated onto the original silicon-based cells through semiconductor processing, integrating the two into a single cell.

However, perovskite cells are still in development and have a considerably shorter lifespan than silicon-based cells. This means that if a perovskite cell fails in a 2T configuration, replacement of the failed perovskite cell becomes impossible. As a result, the 4T cell design has emerged. The key difference is that perovskite and silicon-based cells are fabricated separately and then connected to form a cell assembly, allowing for individual replacement if one cell fails.

Current solar module installation methods only accommodate single modules. Designs for frames, supports, and clamps are all geared towards single-module installation. Therefore, there remains a need in the technology for a frame design that can simultaneously mount and secure multiple-layer modules within the same space.

### SUMMARY OF THE INVENTION

One objective of the present invention is to provide a novel 4T cell module and frame assembly capable of simultaneously fixing and installing two modules on the same frame structure.

One aspect of the present invention provides a tandem solar cell module assembly including a frame, wherein the inner edge of the frame is provided with a flange; a lower solar cell module, disposed in the frame, and the periphery of the lower solar cell module directly contacts the flange and is supported thereby; an upper solar cell module, disposed in the frame and stacked on the lower solar cell module; and a top cover, stacked on the upper solar cell module.

According to an embodiment of the present invention, the frame is a one-piece frame.

According to an embodiment of the present invention, the frame is a combined frame comprising a pair of long side strip structures and a pair of short side strip structures.

According to an embodiment of the present invention, the frame is made of a high-strength and corrosion-resistant metal or insulating material.

According to an embodiment of the present invention, the upper solar cell module is a light-transmissive cell module.

According to an embodiment of the present invention, the light-transmissive cell module comprises a perovskite solar cell module.

According to an embodiment of the present invention, the lower solar cell module is a silicon-based cell module.

According to an embodiment of the present invention, the silicon-based cell module comprises a TOPCon cell module, an HJT cell module, or an xBC cell module.

According to an embodiment of the present invention, the tandem solar cell module assembly further comprises: a buffer strip, disposed between the upper solar cell module and the top cover.

According to an embodiment of the present invention, the buffer strip is pre-fixed or embedded on the lower surface of the top cover.

According to an embodiment of the present invention, a buffer strip is disposed between the upper solar cell module and the top cover, between the upper solar cell module and the lower solar cell module, or between the lower solar cell module and the flange.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic exploded diagram of a tandem solar cell module assembly according to an embodiment of the present invention.

FIG. 2 is a schematic side view diagram of a frame according to another embodiment of the present invention.

FIG. 3 is a schematic top view diagram of a tandem solar cell module assembly according to another embodiment of the present invention.

FIG. 4 is a schematic cross-sectional diagram taken along line I-I′ in FIG. 3.

FIG. 5 is a schematic cross-sectional diagram taken along line II-II′ in FIG. 3.

FIG. 6 is a schematic top view diagram of a tandem solar cell module assembly according to still another embodiment of the present invention.

FIG. 7 is a schematic cross-sectional diagram taken along line I-I′ in FIG. 6.

FIG. 8 is a schematic cross-sectional diagram taken along line II-II′ in FIG. 6.

### DETAILED DESCRIPTION

Hereinafter, details will be described with reference to the accompanying drawings, and the content of these drawings also constitutes a part of the detailed description of the specification, and is illustrated by way of specific examples that can implement the embodiments. The following embodiments have described sufficient details to enable those skilled in the art to implement them.

Of course, other embodiments may also be adopted, or any structural, logical, and electrical changes may be made without departing from the embodiments described herein. Therefore, the following detailed description should not be regarded as limiting. On the contrary, the embodiments contained therein will be defined by the appended claims.

The present invention provides a novel 4T cell/module frame structure that can simultaneously fix and install two (or more) cell modules on the same frame structure, for example, a stacked module of perovskite cell modules and TOPCon cell modules, which has attracted much attention recently.

The newly designed solar module frame structure can accommodate two or more layers of cell modules that are simultaneously mounted and secured in the same frame space, for example, an upper perovskite cell module combined with an independent, lower TOPCon cell module, which combines the advantages of their respective conversion wavelengths to achieve the purpose of improving power generation efficiency. In addition, the newly designed solar module frame structure can also facilitate future maintenance and replacement.

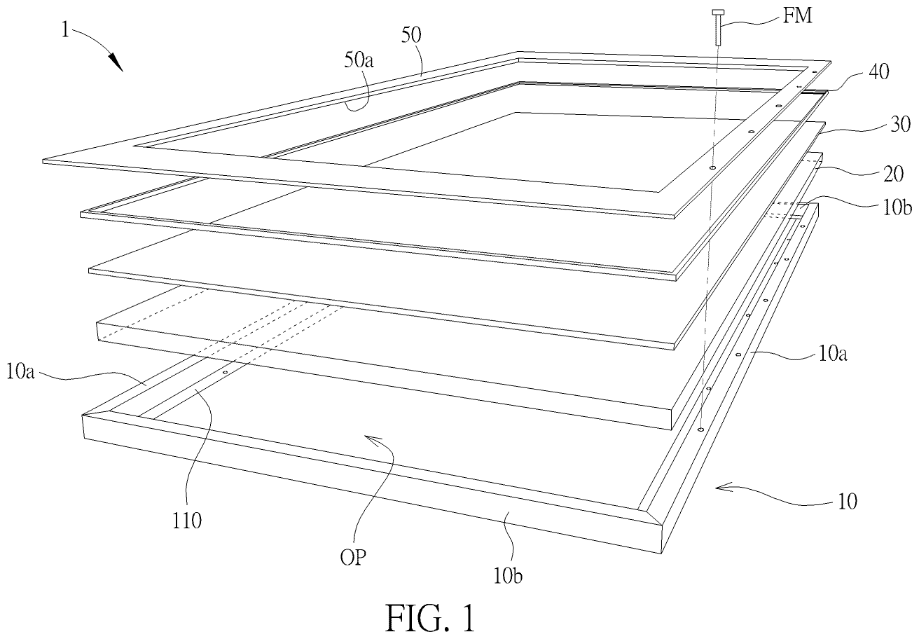

Please refer to FIG. 1, which is a schematic exploded diagram of a tandem solar cell module assembly according to an embodiment of the present invention. As shown in FIG. 1, the tandem solar cell module assembly 1 includes a frame 10, wherein the frame 10 has a flange 110 disposed along the inner perimeter of the frame 10. According to an embodiment of the present invention, the frame 10 has a central opening OP for receiving solar cell modules. According to an embodiment of the present invention, the frame 10 includes a pair of long side strip structures 10a and a pair of short side strip structures 10b.

According to an embodiment of the present invention, the tandem solar cell module assembly 1 further includes a lower solar cell module 20, disposed in the central opening OP of the frame 10, and the bottom periphery of the lower solar cell module 20 is in direct contact with the flange 110 of the frame 10 and is supported thereby. According to an embodiment of the present invention, for example, the lower solar cell module 20 may be a silicon-based solar cell module, such as a Tunnel Oxide Passivated Contact (TOPCon) cell module, a Heterojunction (HJT) cell module, or an Interdigitated Back Contact (xBC) cell module.

According to an embodiment of the present invention, the tandem solar cell module assembly 1 further includes an upper solar cell module 30, disposed in the central opening OP of the frame 10 and stacked on the lower solar cell module 20. According to an embodiment of the present invention, for example, the upper solar cell module 30 may be a light-transmissive, wide bandgap (or ultra-wide bandgap) cell module, such as a perovskite solar cell module.

According to an embodiment of the present invention, the size of the central opening OP is approximately equal to the size of the lower solar cell module 20 and the size of the upper solar cell module 30, such that the upper solar cell module 30 and the lower solar cell module 20 can be suitably accommodated within the frame 10. According to an embodiment of the present invention, the upper solar cell module 30 and the lower solar cell module 20 can be the same size, or the upper solar cell module 30 and the lower solar cell module 20 can be different sizes, for example, in a one-to-two or one-to-three configuration.

According to an embodiment of the present invention, the upper solar cell module 30 and the lower solar cell module 20 can be frameless solar cell modules or framed solar cell modules.

According to an embodiment of the present invention, the tandem solar cell module assembly 1 further includes an annular top cover 50 for pressing down on the periphery of the upper solar cell module 30. According to an embodiment of the present invention, the annular top cover 50 can be locked onto the frame 10 by fixing means such as screws FM. According to an embodiment of the present invention, the top cover 50 is made of, for example, a high-strength and corrosion-resistant metal or insulating material, and it also has an opening 50a with a size similar to the central opening OP of the frame 10.

According to an embodiment of the present invention, to avoid damage to the upper solar cell module 30 due to stress, a buffer strip 40 can be additionally provided between the upper solar cell module 30 and the top cover 50. According to an embodiment of the present invention, the buffer strip 40 can be continuous or discontinuous. According to an embodiment of the present invention, the buffer strip 40 can be pre-fixed or embedded on the lower surface of the top cover 50.

According to an embodiment of the present invention, the flange 110 of the frame 10 can be continuous or discontinuous, and its width is less than or equal to the peripheral inactive area of the lower solar cell module 20.

According to an embodiment of the present invention, the frame 10 can be a one-piece frame, but it is not limited thereto. According to another embodiment of the present invention, the frame 10 can be a combined structure. For example, the pair of long side strip structures 10a and the pair of short side strip structures 10b can be separated into individual components for easy transportation and installation.

According to an embodiment of the present invention, the frame 10 is made of, for example, a high-strength and corrosion-resistant metal or insulating material. According to an embodiment of the present invention, the frame 10 can be made of the same material as a general solar cell frame. According to an embodiment of the present invention, the frame 10 can be made of common C-shaped steel, stainless steel, engineering plastics, or other corrosion-resistant insulating materials. The solar module frame structure design of the present invention is a fixing solution for stacking the upper solar cell module 30 on top of the lower solar cell module 20 (for example, a TOPCon cell module) to meet the installation requirements of 4T modules, thereby achieving the purpose of power enhancement while also solving the problems of insufficient lifespan and inability for timely replacement of existing perovskite cell modules.

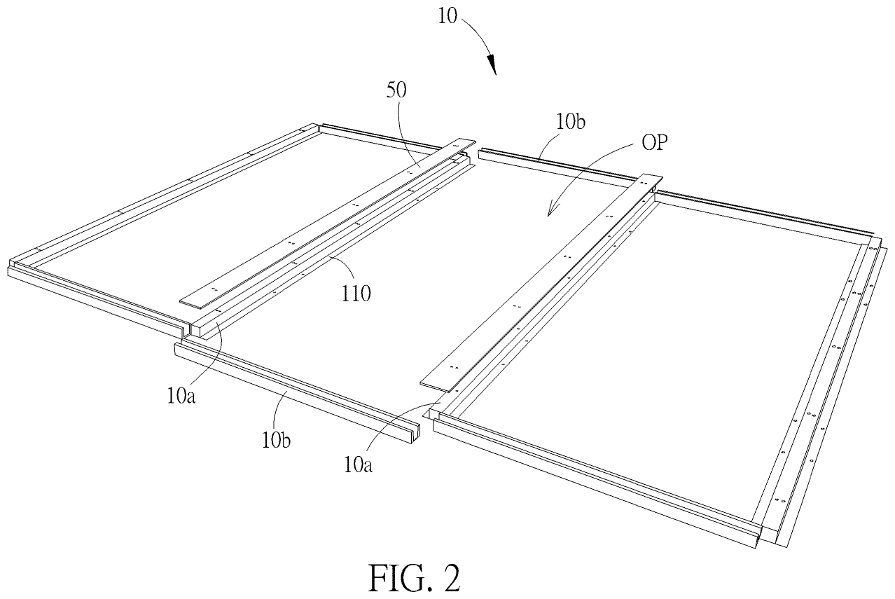

Please refer to FIG. 2, which is a schematic side view illustrating a frame according to another embodiment of the present invention, wherein the same or similar elements, layers, or materials are still represented by the same numeral numbers or labels. As shown in FIG. 2, the frame 10 is a combined structure, for example, composed of a plurality of long side strip structures 10a (four are illustrated in the figure) and a plurality of short side strip structures 10b (six are illustrated in the figure), having a plurality of central openings OP for receiving solar cell modules (omitted in the figure). The bottom inner edge of the frame 10 is provided with a flange 110.

According to an embodiment of the present invention, the frame 10 has a plurality of central openings OP (three are illustrated in the figure) for receiving a plurality of solar cell modules.

In FIG. 2, the middle two long side strip structures 10a and the top cover 50 can be shared. Furthermore, the top cover 50 can be elongated rather than annular, and it is fixed to the long side strip structures 10a. Of course, in some embodiments, the middle two long side strip structures 10a can also be non-shared. For example, each long side strip structure 10a in the figure can be divided into two and placed side by side.

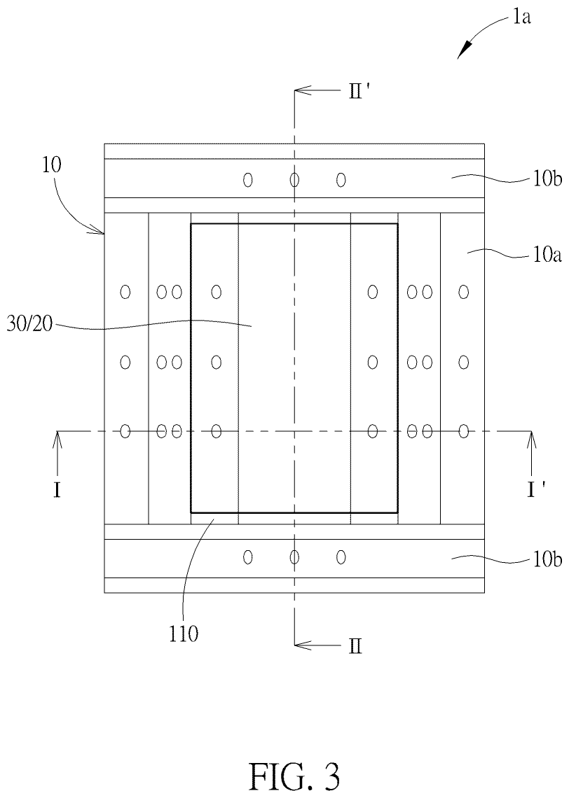

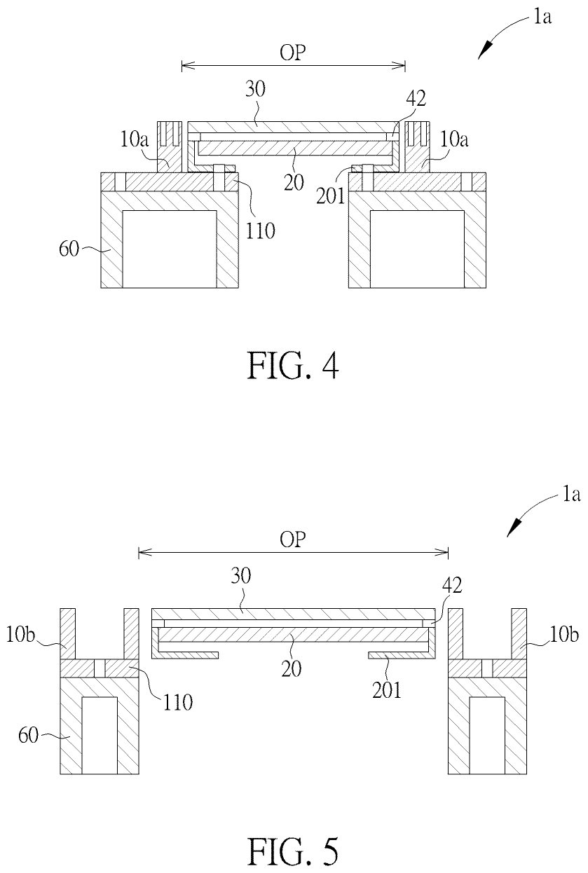

Please refer to FIGS. 3 to 5, wherein FIG. 3 is a schematic top view illustrating a tandem solar cell module assembly according to another embodiment of the present invention, FIG. 4 is a schematic cross-sectional view taken along the line I-I′ in FIG. 3, and FIG. 5 is a schematic cross-sectional view taken along the line II-II′ in FIG. 3, wherein the same or similar elements, layers, or materials are still represented by the same numeral numbers or labels.

As shown in FIGS. 3 to 5, the tandem solar cell module assembly la includes a frame 10, wherein the bottom inner edge of the frame 10 is provided with a flange 110. According to an embodiment of the present invention, the frame 10 has a central opening OP for receiving solar cell modules. According to an embodiment of the present invention, the frame 10 is a combined structure, including a pair of long side strip structures 10a and a pair of short side strip structures 10b, which can be separated into individual components for easy transportation and installation.

According to an embodiment of the present invention, the frame 10 is made of, for example, a high-strength and corrosion-resistant metal or insulating material. According to an embodiment of the present invention, the frame 10 can be made of the same material as a general solar cell frame. According to an embodiment of the present invention, the frame 10 can be made of common C-shaped steel, stainless steel, engineering plastics, or other corrosion-resistant insulating materials. According to an embodiment of the present invention, the frame 10 can be locked onto a metal bracket 60 using screws or other means.

According to an embodiment of the present invention, the tandem solar cell module assembly la further includes a lower solar cell module 20, disposed in the central opening OP of the frame 10. According to an embodiment of the present invention, the lower solar cell module 20 is a framed solar cell module, and its bottom frame 201 directly contacts the flange 110 of the frame 10 and is supported thereby. According to an embodiment of the present invention, the flange 110 of the frame 10 can be continuous or discontinuous, and its width is less than or equal to the peripheral inactive area of the lower solar cell module 20. According to an embodiment of the present invention, for example, the lower solar cell module 20 can be a silicon-based solar cell module such as a TOPCon cell module, an HJT cell module, or an xBC cell module.

According to an embodiment of the present invention, the tandem solar cell module assembly la further includes an upper solar cell module 30, also disposed in the central opening OP of the frame 10 and stacked on the lower solar cell module 20. According to an embodiment of the present invention, for example, the upper solar cell module 30 may be a light-transmissive, wide bandgap (or ultra-wide bandgap) cell module, such as a perovskite solar cell module. According to an embodiment of the present invention, a buffer strip 42 can optionally be provided between the lower solar cell module 20 and the upper solar cell module 30.

According to an embodiment of the present invention, the size of the central opening OP is approximately equal to the size of the lower solar cell module 20 and the size of the upper solar cell module 30, such that the upper solar cell module 30 and the lower solar cell module 20 can be suitably accommodated within the frame 10. According to an embodiment of the present invention, the upper solar cell module 30 and the lower solar cell module 20 can be the same size, or the upper solar cell module 30 and the lower solar cell module 20 can be different sizes, for example, in a one-to-two or one-to-three configuration.

According to an embodiment of the present invention, the tandem solar cell module assembly la can further include a top cover 50 as shown in FIG. 1, for pressing down on the periphery of the upper solar cell module 30. For the sake of simplicity, the top cover 50 is not shown in FIGS. 3 to 5.

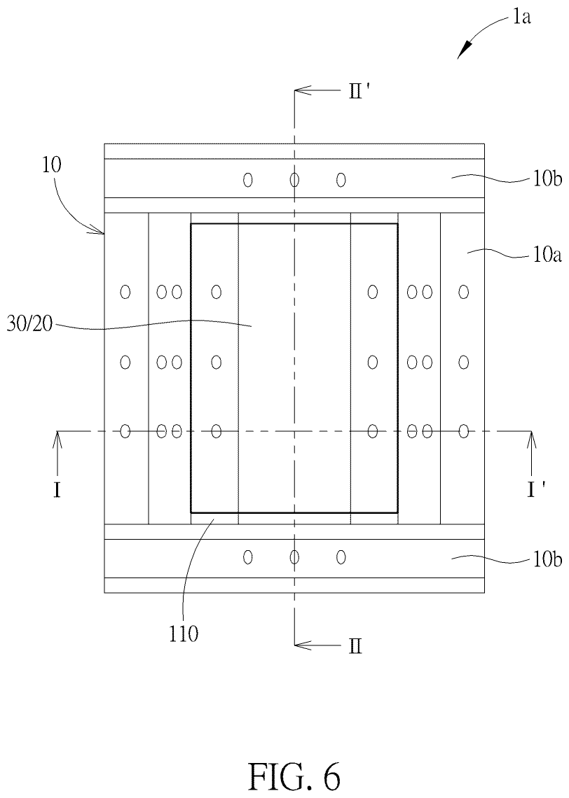

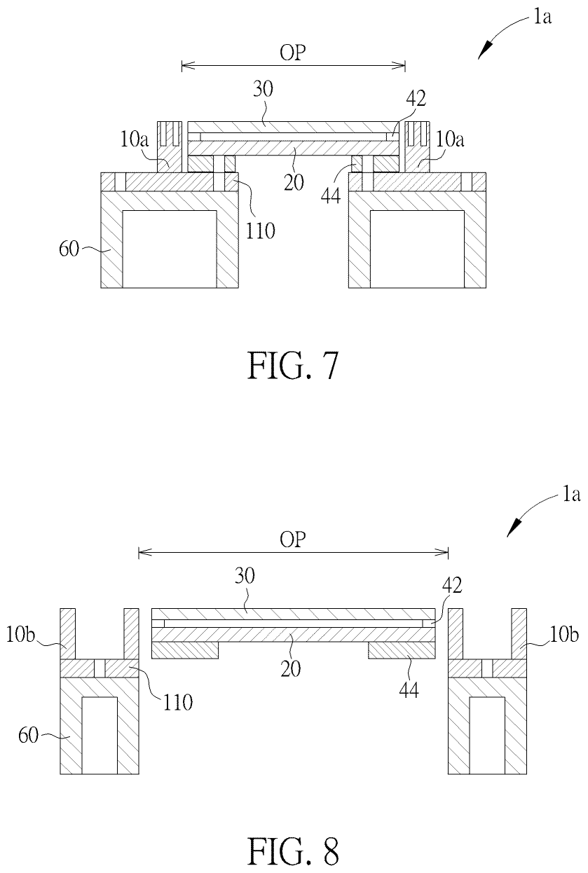

Please refer to FIGS. 6 to 8, wherein FIG. 6 is a schematic top view illustrating a tandem solar cell module assembly according to another embodiment of the present invention, FIG. 7 is a schematic cross-sectional view taken along the line I-I′ in FIG. 6, and FIG. 8 is a schematic cross-sectional view taken along the line II-II′ in FIG. 6, wherein the same or similar elements, layers, or materials are still represented by the same numeral numbers or labels.

As shown in FIGS. 6 to 8, the tandem solar cell module assembly 1b includes a frame 10, wherein the bottom inner edge of the frame 10 is provided with a flange 110. According to an embodiment of the present invention, the frame 10 has a central opening OP for receiving solar cell modules. According to an embodiment of the present invention, the frame 10 is a combined structure, including a pair of long side strip structures 10a and a pair of short side strip structures 10b, which can be separated into individual components for easy transportation and installation.

According to an embodiment of the present invention, the frame 10 is made of, for example, a high-strength and corrosion-resistant metal or insulating material. According to an embodiment of the present invention, the frame 10 can be made of the same material as a general solar cell frame. According to an embodiment of the present invention, the frame 10 can be made of common C-shaped steel, stainless steel, engineering plastics, or other corrosion-resistant insulating materials. According to an embodiment of the present invention, the frame 10 can be locked onto a metal bracket 60 using screws or other means.

According to an embodiment of the present invention, the tandem solar cell module assembly 1b further includes a lower solar cell module 20, disposed in the central opening OP of the frame 10. According to an embodiment of the present invention, the lower solar cell module 20 is a frameless solar cell module, supported by the flange 110 of the frame 10. According to an embodiment of the present invention, a buffer strip 44 is provided between the flange 110 and the lower solar cell module 20. According to an embodiment of the present invention, the flange 110 of the frame 10 can be continuous or discontinuous, and its width is less than or equal to the peripheral inactive area of the lower solar cell module 20. According to an embodiment of the present invention, for example, the lower solar cell module 20 can be a silicon-based solar cell module such as a TOPCon cell module, an HJT cell module, or an xBC cell module.

According to an embodiment of the present invention, the tandem solar cell module assembly 1b further includes an upper solar cell module 30, also disposed in the central opening OP of the frame 10 and stacked on the lower solar cell module 20. According to an embodiment of the present invention, for example, the upper solar cell module 30 may be a light-transmissive, wide bandgap (or ultra-wide bandgap) cell module, such as a perovskite solar cell module.

According to an embodiment of the present invention, a buffer strip 42 can optionally be provided between the lower solar cell module 20 and the upper solar cell module 30.

According to an embodiment of the present invention, the size of the central opening OP is approximately equal to the size of the lower solar cell module 20 and the size of the upper solar cell module 30, such that the upper solar cell module 30 and the lower solar cell module 20 can be suitably accommodated within the frame 10. According to an embodiment of the present invention, the upper solar cell module 30 and the lower solar cell module 20 can be the same size, or the upper solar cell module 30 and the lower solar cell module 20 can be different sizes, for example, in a one-to-two or one-to-three configuration.

According to an embodiment of the present invention, the tandem solar cell module assembly 1b can further include a top cover 50 as shown in FIG. 1, for pressing down on the periphery of the upper solar cell module 30. For the sake of simplicity, the top cover 50 is not shown in FIGS. 6 to 8.

Those skilled in the art will readily observe that numerous modifications and alterations of the device and method may be made while retaining the teachings of the invention. Accordingly, the above disclosure should be construed as limited only by the metes and bounds of the appended claims.

1. A tandem solar cell module assembly, comprising:
a frame, having an inverted T-shaped cross-sectional profile, wherein an inner edge of the frame is provided with a flange;
a lower solar cell module, which is a framed solar cell module having a bottom frame, disposed in the frame, and the bottom frame directly contacts the flange and is supported thereby, so that the lower solar cell module is spaced apart from a body of the frame;
an upper solar cell module, disposed in the frame and stacked on the lower solar cell module, wherein a top surface of the upper solar cell module is coplanar with a top surface of the frame; and
an annular top cover, stacked on the upper solar cell module, wherein the annular top cover presses down on a periphery of the upper solar cell module, and is locked onto a top surface of the frame.

2. The tandem solar cell module assembly according to claim 1, wherein the frame is a one-piece frame.

3. The tandem solar cell module assembly according to claim 1, wherein the frame is a combined frame comprising a pair of long side strip structures and a pair of short side strip structures.

4. The tandem solar cell module assembly according to claim 1, wherein the frame is made of a corrosion-resistant metal or insulating material.

5. The tandem solar cell module assembly according to claim 1, wherein the upper solar cell module is a light-transmissive cell module.

6. The tandem solar cell module assembly according to claim 5, wherein the light-transmissive cell module comprises a perovskite solar cell module.

7. The tandem solar cell module assembly according to claim 1, wherein the lower solar cell module is a silicon-based cell module.

8. The tandem solar cell module assembly according to claim 7, wherein the silicon-based cell module comprises a TOPCon cell module, an HJT cell module, or an xBC cell module.

9. The tandem solar cell module assembly according to claim 1, further comprising: a first buffer strip, disposed between the upper solar cell module and the annular top cover.

10. The tandem solar cell module assembly according to claim 9, wherein the first buffer strip is pre-fixed or embedded on a lower surface of the annular top cover.

11. The tandem solar cell module assembly according to claim 9, wherein a second buffer strip is disposed between the upper solar cell module and the lower solar cell module, and a third buffer strip is disposed between the lower solar cell module and the flange.

12. (canceled)
